(19) United States
(12) Patent Application Publication
(10) Pub. No.: US 2023/0207303 A1
(43) Pub. Date: Jun. 29, 2023

(54) SEMICONDUCTOR PACKAGING METHOD

(71) Applicants: Semiconductor Manufacturing International (Beijing) Corporation, Beijing (CN); Semiconductor Manufacturing International (Shanghai) Corporation, Shanghai (CN)

(72) Inventors: Qingzhao LIU, Shanghai (CN); Rex YAN, Shanghai (CN); Yajun ZHAO, Shanghai (CN); Elegant LIU, Shanghai (CN); Yang WANG, Shanghai (CN)

(73) Assignees: Semiconductor Manufacturing International (Beijing) Corporation, Beijing (CN); Semiconductor Manufacturing International (Shanghai) Corporation, Shanghai (CN)

(21) Appl. No.: 18/068,586

(22) Filed: Dec. 20, 2022

(30) Foreign Application Priority Data
Dec. 23, 2021 (CN) 202111594481.X

(51) Int. Cl. H01L 21/02; H01L 23/00; H01L 25/065; H01L 21/3105

(52) U.S. Cl. CPC H01L 21/02035; H01L 21/0214; H01L 21/0228; H01L 21/02016; H01L 21/02021; H01L 21/31053; H01L 24/29; H01L 24/32; H01L 24/83; H01L 25/0657; H01L 2224/29187; H01L 2224/32145; H01L 2224/83894; H01L 2225/06524; H01L 2225/06568; H01L 2924/1011

(57) ABSTRACT

The present disclosure relates to a semiconductor packaging method. The method includes: providing a first wafer; and performing a wafer stacking operation a plurality of times. The wafer stacking operation includes: forming a first to-be-bonded wafer in the shape of a boss, where the first to-be-bonded wafer includes a base and a protrusion from the base, and orientating the protrusion toward a second to-be-bonded wafer and bonding the protrusion to the second to-be-bonded wafer; forming a first dielectric layer on a surface of the protrusion; and performing second trimming on an edge region of the protrusion and an edge region of the second to-be-bonded wafer, so that the remainder of the second to-be-bonded wafer after the second trimming is in the shape of a boss, and using the remainder of the wafer stack after the second trimming as the first to-be-bonded wafer for next wafer stacking.

### CROSS REFERENCE TO RELATED APPLICATIONS

This application is based on and claims priority to Chinese patent Application No. 202111594481.X, filed Dec. 23, 2021, the entire content of which is incorporated herein by reference.

### TECHNICAL FIELD

The present disclosure relates to the field of semiconductor manufacturing, and in particular, to a semiconductor packaging method.

### BACKGROUND

In some existing semiconductor processes, for example, in the 3D-IC wafer bonding and subsequent wafer thinning processes, a wafer needs to be trimmed to ensure the integrity and smoothness of a wafer edge. Before two adjacent wafers are bonded, one of the wafers needs to be trimmed for the first time, and then the two adjacent wafers are bonded. The wafer on a top layer is first ground and thinned, and then a second trimming process is adopted to obtain a desired edge. The previous steps are repeated in a multi-wafer stacking process.

### SUMMARY

The forms of the present disclosure provide a semiconductor packaging method, to improve the performance of a semiconductor structure.

In an aspect of the present disclosure, a semiconductor packaging method is provided. The method may include: providing a first wafer; and performing a wafer stacking operation a plurality of times, where the wafer stacking operation includes: forming a first to-be-bonded wafer in the shape of a boss, the first to-be-bonded wafer including a base and a protrusion protruding from the base, and the forming a first to-be-bonded wafer including: performing a first trimming on an edge region of a front side of the first wafer, and using the remainder of the first wafer after the first trimming as the first to-be-bonded wafer; orientating the protrusion toward a second to-be-bonded wafer and bonding the protrusion to the second to-be-bonded wafer, to form a wafer stack; thinning a back side of the first to-be-bonded wafer after the bonding, a thickness for the thinning being at least a thickness of the base; forming a first dielectric layer on a surface of the protrusion after the thinning, a corner of the first dielectric layer being arc-shaped; and performing a second trimming on an edge region of the protrusion and an edge region of the second to-be-bonded wafer after the first dielectric layer is formed, so that the remainder of the second to-be-bonded wafer after the second trimming is in the shape of a boss, and using the remainder of the wafer stack after the second trimming as the first to-be-bonded wafer for next wafer stacking.

Compared with the prior art, the forms of the present disclosure has the following advantages.

In the semiconductor packaging method provided in the forms of the disclosure, a wafer stacking operation is performed a plurality of times. The wafer stacking operation includes: orientating the protrusion toward a second to-be-bonded wafer and bonding the protrusion to the second to-be-bonded wafer, to form a wafer stack; thinning a back side of the first to-be-bonded wafer after the bonding, a thickness for the thinning being at least a thickness of the base; forming a first dielectric layer on a surface of the protrusion after the thinning, a corner of the first dielectric layer being arc-shaped. During the second trimming, since the corner of the first dielectric layer is arc-shaped, and the first dielectric layer is closely attached to the surface of the protrusion and the surface of the second to-be-bonded wafer, the damage to a tool used for the second trimming is reduced. Accordingly, a probability that a residue remains on the surface of the second to-be-bonded wafer is reduced in the subsequent thinning process, thereby improving the performance of the semiconductor structure.

### BRIEF DESCRIPTION OF THE DRAWINGS

FIGS. 1 to 5 are schematic structural diagrams corresponding to steps in a semiconductor packaging method.

FIGS. 6 to 13 are schematic structural diagrams corresponding to steps in a form of a semiconductor packaging method according to the present disclosure.

### DETAILED DESCRIPTION

Currently, the performance of a semiconductor structure is to be improved. A reason why the performance of the semiconductor structure is to be improved is analyzed according to a semiconductor packaging method.

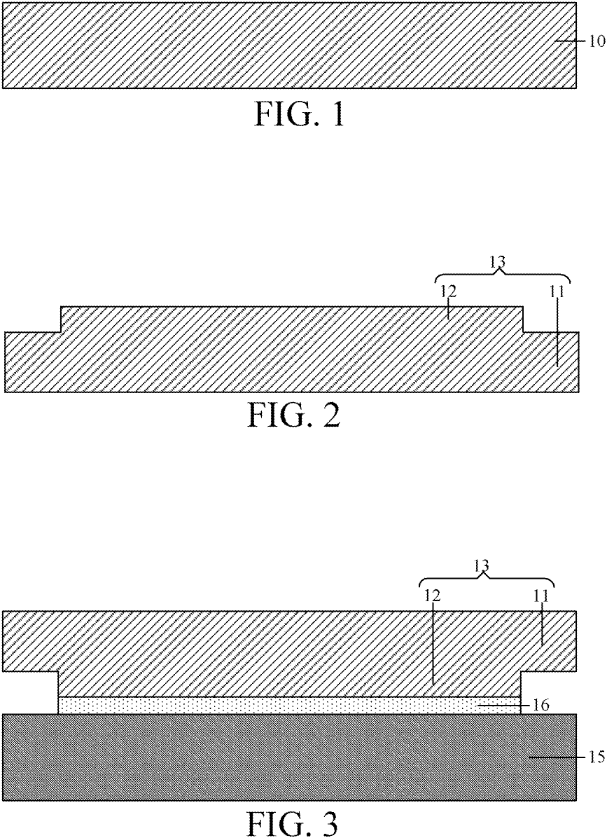

FIG. 1 to FIG. 5 are schematic structural diagrams corresponding to steps in a semiconductor packaging method.

Referring to FIG. 1, a first wafer 10 is provided.

Referring to FIG. 2, first trimming is performed on the first wafer 10 to form a first to-be-bonded wafer 13 in the shape of a boss. The first to-be-bonded wafer 13 includes a base 11 and a protrusion 12 protruding from the base 11.

Referring to FIG. 3, the protrusion 12 is orientated toward a second to-be-bonded wafer 15, and the first to-be-bonded wafer 13 and the second to-be-bonded wafer 15 are bonded through a bonding layer 16.

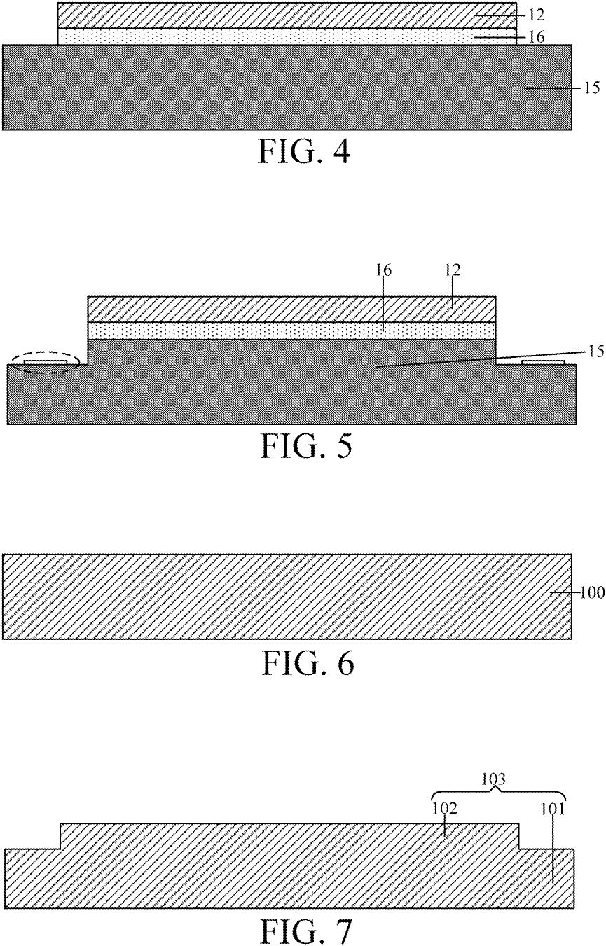

Referring to FIG. 4, a back side of the first to-be-bonded wafer 13 is thinned after the bonding. A thickness for the thinning is at least a thickness of the base 11.

Referring to FIG. 5, second trimming is performed on an edge region of the protrusion 12 and an edge region of the second to-be-bonded wafer 15 after the thinning, and the remainder of the second to-be-bonded wafer 15 after the second trimming is in the shape of a boss.

It is found through research that since a corner of an edge region of the first wafer 10 is a right angle, the corner of the edge region of the first wafer 10 may cause certain damage to a tool used for the first trimming during the first trimming, and during the second trimming subsequently, further damage may occur to the tool (for example, a blade) that has been damaged to some extent (for example, a large groove-shaped loss exists on the blade). Accordingly, when the tool that has been damaged to some extent is adopted for the second trimming, a residue may remain on a surface of the remainder of the second to-be-bonded wafer 15 (shown by a dashed circle in FIG. 5), which affects the performance of the semiconductor structure.

In order to address the above technical problem, a form of the present disclosure provides a semiconductor packaging method, including: providing a first wafer; and performing a wafer stacking operation a plurality of times, where the wafer stacking operation includes: forming a first to-be-bonded wafer in the shape of a boss, where the first to-be-bonded wafer includes a base and a protrusion protruding from the base, and the forming a first to-be-bonded wafer includes: performing first trimming on an edge region of a front side of the first wafer, and using the remainder of the first wafer after the first trimming as the first to-be-bonded wafer; orientating the protrusion toward a second to-be-bonded wafer and bonding the protrusion to the second to-be-bonded wafer, to form a wafer stack; thinning a back side of the first to-be-bonded wafer after the bonding, where a thickness for the thinning is at least a thickness of the base; forming a first dielectric layer on a surface of the protrusion after the thinning, where a corner of the first dielectric layer is arc-shaped; and performing second trimming on an edge region of the protrusion and an edge region of the second to-be-bonded wafer after the first dielectric layer is formed, so that the remainder of the second to-be-bonded wafer after the second trimming is in the shape of a boss, and using the remainder of the wafer stack after the second trimming as the first to-be-bonded wafer for next wafer stacking.

In the solution disclosed in the form of the present disclosure, the wafer stacking operation is performed a plurality of times. The wafer stacking operation includes: orientating the protrusion toward a second to-be-bonded wafer and bonding the protrusion to the second to-be-bonded wafer, to form a wafer stack; thinning a back side of the first to-be-bonded wafer after the bonding, where a thickness for the thinning is at least a thickness of the base; forming a first dielectric layer on a surface of the protrusion after the thinning, where a corner of the first dielectric layer is arc-shaped. During the second trimming, since the corner of the first dielectric layer is arc-shaped, the damage to a tool used for the second trimming is reduced. Accordingly, a probability that a residue remains on the surface of the second to-be-bonded wafer is reduced in the subsequent thinning process, thereby improving the performance of the semiconductor structure.

In order to make the foregoing objectives, features, and advantages of the forms of the present disclosure more apparent and easier to understand, specific forms of the present disclosure are described in detail below with reference to the accompanying drawings.

FIG. 6 to FIG. 13 are schematic structural diagrams corresponding to steps in a form of a semiconductor packaging method according to the present disclosure.

Referring to FIG. 6, a first wafer 100 is provided.

The first wafer 100 provides a process basis for performing first trimming subsequently, and the first wafer 100 is configured to be bonded to other wafers.

The first wafer 100 is a finished wafer, and the first wafer 100 may be made using an integrated circuit fabrication technology.

In this form, the first wafer 100 includes a first substrate, a device such as an NMOS device and a PMOS device formed on the first substrate through processes such as deposition and etching, and a structure such as a dielectric layer and a metal interconnecting wire formed on the device.

In this form, the first substrate is a silicon substrate. In other forms, a material of the first substrate may further be other materials such as germanium, silicon germanium, silicon carbide, gallium arsenide, or indium gallium, and the first substrate may further be other types of substrates such as a silicon substrate on an insulator or a germanium substrate on an insulator. The material of the first substrate may be a material suitable for process requirements or easy to integrate.

Referring to FIG. 7 to FIG. 13, the wafer stacking operation is performed a plurality of times.

With a minimum line width increasingly approaching a physical limit, the idea of Moore’s Law gradually becomes infeasible.

The wafer stacking operation a plurality of times is intended to increase a wiring (device) density per unit volume by superimposing a plurality of wafer layers.

The steps of the wafer stacking operation are described in detail below with reference to the accompanying drawings.

Referring to FIG. 7, a first to-be-bonded 103 wafer in the shape of a boss is formed. The first to-be-bonded includes a base 101 and a protrusion 102 protruding from the base 101. The formation of the first to-be-bonded wafer 103 includes: performing first trimming on an edge region of a front side of the first wafer 100, and using the remainder of the first wafer 100 after the first trimming as the first to-be-bonded wafer 103.

Specifically, during the first trimming, since the edge region of the front side of the first wafer is generally not flat enough, a gap may exist during subsequent bonding between the first wafer and other wafers. Therefore, an uneven part of the edge region of the front side of the first wafer is removed through the first trimming, which reduces the probability that the gap occurs at a bonding surface between the first wafer and other wafers, thereby improving bonding reliability.

In this form, a blade is used to perform the first trimming.

Specifically, the first wafer 100 is mechanically worn through rotation of the blade to achieve the effect of trimming.

In this form, the blade is a circular blade.

The circular blade mechanically wears the first wafer 100 through uniform rotation to achieve the effect of trimming.

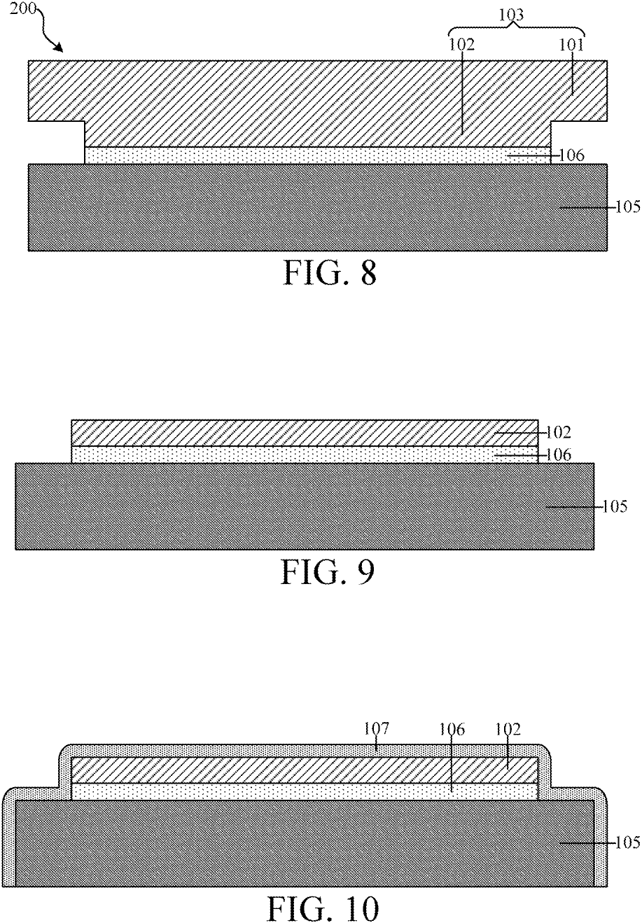

Referring to FIG. 8, the protrusion 102 is orientated toward a second to-be-bonded wafer 105 and bonded to the second to-be-bonded wafer 105, to form a wafer stack 200.

Compared with a conventional wafer in which all modules are placed on a same surface, a wafer stack allows for stacking of a plurality of wafers, and communication of the wafer stack in a vertical direction is realized using the through-silicon-via (TSV) technology, thereby improving the performance and integration of the device.

In this form, a process of bonding the protrusion 102 to the second to-be-bonded wafer 105 is a fusion bonding process.

In other forms, the process of bonding the protrusion to the second to-be-bonded wafer may further be one or more of a hybrid bonding process, a temporary bonding process, an adhesive bonding process, an anodic bonding process, or a salient point bonding process.

It would be appreciated that the first to-be-bonded wafer 103 and the second to-be-bonded wafer 105 are bonded through a bonding layer 106.

Specifically, a material of the bonding layer 106 is one or more of silicon oxide, silicon nitride, or silicon carbonitride.

Materials of the silicon oxide, silicon nitride, and silicon carbonitride are all commonly used materials in the bonding process, and have strong bonding ability, so that the bonding strength between the protrusion 102 and the second to-be-bonded wafer 105 can satisfy the process requirement.

Referring to FIG. 9, a back side of the first to-be-bonded wafer 103 is thinned after the bonding. A thickness for the thinning is at least a thickness of the base 101.

Specifically, the thinning of the back side of the first to-be-bonded wafer 103 provides a process basis for the subsequent second trimming and another wafer stacking operation.

In this form, the back side of the first to-be-bonded wafer 103 is thinned through rough grinding and then fine grinding. The rough grinding is performed quickly using a rough grinding machine, and the fine grinding is performed, for example, using a chemical mechanical grinding process.

Referring to FIG. 10, a first dielectric layer 107 is formed on a surface of the protrusion 102 after the thinning. A corner of the first dielectric layer 107 is arc-shaped.

Specifically, the first dielectric layer 107 is formed on the surface of the protrusion, the corner of the first dielectric layer 107 is arc-shaped, and the first dielectric layer 107 is closely attached to the surface of the protrusion 102 and the surface of the second to-be-bonded wafer 105. During the subsequent second trimming, since the corner of the first dielectric layer 107 is arc-shaped, the damage to the tool used for the second trimming is reduced (for example, a groove-shaped loss is caused to the blade). Accordingly, a probability that a residue remains on the surface of the second to-be-bonded wafer 105 is reduced in the subsequent thinning process, thereby improving the performance of the semiconductor structure.

In this form, the process of forming the first dielectric layer 107 includes an atomic layer deposition process.

Specifically, the atomic layer deposition process includes performing an atomic layer deposition cycle a plurality of times, which has superior step coverage, can help improve the thickness uniformity of the first dielectric layer 107, and causes the first dielectric layer 107 to cover the surface and the corner of the protrusion 102, so that the corner of the first dielectric layer 107 is prone to be arc-shaped.

In other forms, the first dielectric layer may also be formed using the chemical vapor deposition process. Based on the coverage of the chemical vapor deposition process itself, the corner of the first dielectric layer may also be arc-shaped.

In this form, in the process of forming the first dielectric layer 107, the first dielectric layer 107 further covers a top surface and a side wall of the second to-be-bonded wafer 105, and the first dielectric layer 107 is arc-shaped at the corner of the second to-be-bonded wafer 105.

It would be appreciated [BSl]that the first dielectric layer 107 is arc-shaped at the corner of the second to-be-bonded wafer 105, and the probability of damage to the blade is reduced during the subsequent second trimming on the edge region of the front side of the second to-be-bonded wafer 105.

In this form, a material of the first dielectric layer 107 includes one or more of silicon oxide, silicon nitride, silicon oxynitride, and silicon carbonitride.

Specifically, the silicon oxide, silicon nitride, silicon oxynitride, and silicon carbonitride are all commonly used materials for a dielectric film layer. In the process of forming the first dielectric layer 107 using the deposition process, the first dielectric layer 107 may be attached to the surface of the protrusion, and the first dielectric layer 107 is arc-shaped at the corner of the second to-be-bonded wafer 105.

It would be appreciated that a thickness of the first dielectric layer 107 should be neither excessively large nor excessively small. If the thickness of the first dielectric layer 107 is excessively large, the process difficulty of subsequently performing the second trimming on the edge region of the protrusion 102 and the edge region of the second to-be-bonded wafer 105 is increased, and the process efficiency is reduced while the probability of the damage to the blade is increased. If the thickness of the first dielectric layer 107 is excessively small, the cladding of the corners of the protrusion 102 by the first dielectric layer 107 may worsen. During the subsequent second trimming on the edge region of the protrusion 102 and the edge region of the second to-be-bonded wafer 105, the effect of protecting the tool used for the second trimming is reduced, and the probability of damage to the tool used for the second trimming is increased. Accordingly, a higher probability that the residue remains on the surface of the second to-be-bonded wafer 105 in the subsequent thinning process still exists. Therefore, in this form, the thickness of the first dielectric layer 107 ranges from 500 nanometers to 2900 nanometers.

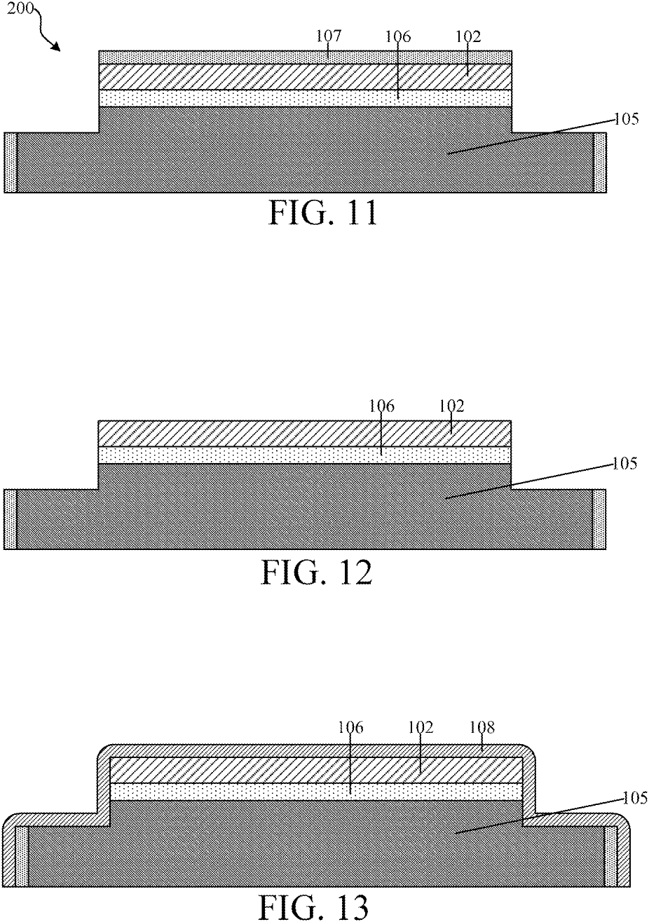

Referring to FIG. 11, second trimming is performed on an edge region of the protrusion 102 and an edge region of the second to-be-bonded wafer 105 after the first dielectric layer 107 is formed, so that the remainder of the second to-be-bonded wafer 105 after the second trimming is in the shape of a boss, and the remainder of the wafer stack 200 after the second trimming is used as the first to-be-bonded wafer for next wafer stacking.

Specifically, after the thinning, an edge gap may occur between the edge region of the protrusion 102 and an interface of the second to-be-bonded wafer 105, which may cause a worse effect of edge bonding between the protrusion 102 and the second to-be-bonded wafer 105. Therefore, the second trimming is performed on the edge region of the protrusion 102 and the edge region of the second to-be-bonded wafer 105, and parts of the protrusion 102 and the second to-be-bonded wafer 105 having relatively low bonding strength are removed, to ensure the bonding strength of the remainder of the wafer stack 200 after the second trimming.

Since the same cutting tool is used for the first trimming and the second trimming, the second trimming is performed according to the first trimming mentioned above in this form.

It would be appreciated that a trimming depth should be neither excessively large nor excessively small. If the trimming depth is excessively large, the base of the second to-be-bonded wafer 105 may be completely removed, resulting in a significant reduction in a yield of the product. If the trimming depth is excessively small, the extent to which the edge regions of the second to-be-bonded wafer 105 are removed may be excessively small, which increases the probability that the edge gap may occur between the edge region of the protrusion 102 and the interface of the second to-be-bonded wafer 105, and reduces the bonding strength of the remainder of the wafer stack 200 after the second trimming, thereby affecting the performance of the semiconductor structure. Therefore, in this form, the trimming depth ranges from 20 micrometers to 200 micrometers.

It would be further appreciated that the trimming width should be neither excessively large nor excessively small. If the trimming width is excessively large, an effective area of the remaining device of the wafer stack 200 after the second trimming is excessively small, and the performance of the semiconductor device is degraded. If the trimming width is excessively small, the extent to which the edge regions of the second to-be-bonded wafer 105 are removed may be excessively small, which increases the probability that the edge gap may occur between the edge region of the protrusion 102 and the interface of the second to-be-bonded wafer 105, and reduces the bonding strength of the remainder of the wafer stack 200 after the second trimming, thereby affecting the performance of the semiconductor structure.

It would be appreciated that the process of the second trimming further includes: removing the first dielectric layer 107 covering the edge regions of the protrusion 102 and the edge regions of the second to-be-bonded wafer 105.

Referring to FIG. 12, the first dielectric layer 107 at the top of the protrusion 102 is planarized.

Specifically, after the thinning, the flatness of the top surface of the protrusion 102 is not high and cannot meet the process requirement. Therefore, the first dielectric layer 107 at the top of the protrusion 102 is planarized, which improves the flatness of the top surface of the protrusion 102 and provides a good process basis for next wafer stacking.

In this form, the first dielectric layer 107 is completely removed from the top of the protrusion 102 during the planarization, which improves the flatness of the top surface of the protrusion 102.

In other forms, during the planarization, a partial thickness of the first dielectric layer at the top of the protrusion may also be removed, so that the flatness of the top surface of the remainder of the first dielectric layer is relatively high, which provides a good process basis for the next wafer stacking.

In this form, the process of planarizing the first dielectric layer 107 at the top of the protrusion 102 includes a chemical mechanical polishing process.

Referring to FIG. 13, a second dielectric layer 108 is formed on a side wall of the protrusion 102.

It would be appreciated that in the step of providing the first wafer 100, an interconnecting wire (not shown) is further formed in the protrusion 102, and the first wafer 100 is subjected to the first trimming and the second trimming. Therefore, the second dielectric layer 108 is formed on the side wall of the protrusion 102 to protect the side wall of the protrusion 102, which reduces the probability that the interconnecting wire is exposed to the outside, thereby improving the performance of the semiconductor structure.

In this form, the second dielectric layer 108 is formed on the top and the side wall of the protrusion 102 and the top of the second to-be-bonded wafer 105.

On the one hand, after the second trimming, some wafer particles or powders may remain on the surfaces of the second to-be-bonded wafer 105 and the protrusion 102, and the top surfaces of the protrusion 102 and the second to-be-bonded wafer 105 may be damaged in the process of planarizing the first dielectric layer 107 at the top of the protrusion 102. Therefore, the second dielectric layer 108 is formed on the top and the side wall of the protrusion 102 and the top of the second to-be-bonded wafer 105, which can repair or cover the defects of the top surfaces of the protrusion 102 and the second to-be-bonded wafer 105, thereby improving the product yield.

On the other hand, the second dielectric layer 108 is formed at the top of the protrusion 102, which also provides a basis for the next wafer stacking. The second dielectric layer 108 may be directly used as the bonding layer for the next wafer stacking.

In this form, the process of forming the second dielectric layer 108 includes an atomic layer deposition process or a chemical vapor deposition process.

The atomic layer deposition process is used in an example. Specifically, the atomic layer deposition process includes performing an atomic layer deposition cycle a plurality of times, which has good step coverage, can help improve thickness uniformity of the second dielectric layer 108, and causes the second dielectric layer 108 to cover the top and the side wall of the protrusion 102 and the top of the second to-be-bonded wafer 105.

A material of the second dielectric layer 108 includes one or more of silicon oxide, silicon nitride, silicon oxynitride, and silicon carbonitride.

Specifically, the silicon oxide, silicon nitride, silicon oxynitride, and silicon carbonitride are all commonly used materials for the dielectric film layer, and during the formation of the second dielectric layer 108 using the deposition process, the second dielectric layer may be closely attached to the top and the side wall of the protrusion 102 and the top of the second to-be-bonded wafer 105.

It would be appreciated that a thickness of the second dielectric layer 108 should be neither excessively large nor excessively small. If the thickness of the second dielectric layer 108 is excessively large, the second dielectric layer 108 may cause the wafer stack 200 to generate greater stress, which increases the probability of deformation of the wafer stack 200, thereby affecting the performance of the semiconductor structure. If the thickness of the second dielectric layer 108 is excessively small, the effect of covering the side wall of the protrusion 102 may become worse, and the effect of protecting the interconnecting wire in the protrusion 102 is correspondingly reduced. In addition, during the next wafer stacking, the bonding strength of the second dielectric layer 108 at the top of the protrusion 102 decreases, thereby affecting the performance of the semiconductor structure. Therefore, in this form, the thickness of the second dielectric layer 108 ranges from 50 nanometers to 100 nanometers.

In this form, the remainder of the wafer stack after the second trimming is used as the first to-be-bonded wafer for the next wafer stacking, and the wafer stacking operation is repeated a plurality of times to complete the packaging process. Specific steps of the subsequent wafer stacking operation are the same as the content described above, and the details are not described herein again.

Although the present disclosure is disclosed above, the present disclosure is not limited thereto. Any person skilled in the art can make various changes and modifications without departing from the spirit and the scope of the present disclosure, and therefore the protection scope of the present disclosure should be subject to the scope defined by the claims.

What is claimed is:

1. A semiconductor packaging method, comprising:
providing a first wafer; and
performing a wafer stacking operation a plurality of times, wherein the wafer stacking operation comprises:
forming a first to-be-bonded wafer in the shape of a boss, wherein the first to-be-bonded wafer comprises a base and a protrusion protruding from the base, and where forming the first to-be-bonded wafer comprises: performing a first trimming on an edge region of a front side of the first wafer, and using a remainder of the first wafer after the first trimming as the first to-be-bonded wafer;
orientating the protrusion toward a second to-be-bonded wafer and bonding the protrusion to the second to-be-bonded wafer, to form a wafer stack;
thinning a back side of the first to-be-bonded wafer after the bonding, wherein a thickness for the thinning is at least a thickness of the base;
forming a first dielectric layer on a surface of the protrusion after the thinning, wherein a corner of the first dielectric layer is arc-shaped; and
performing a second trimming on an edge region of the protrusion and an edge region of the second to-be-bonded wafer after the first dielectric layer is formed, so that the remainder of the second to-be-bonded wafer after the second trimming is in the shape of a boss, and using a remainder of the wafer stack after the second trimming as the first to-be-bonded wafer for next wafer stacking.

2. The semiconductor packaging method according to claim 1, wherein the wafer stacking operation further comprises:
forming a second dielectric layer on a side wall of the protrusion after the second trimming.

3. The semiconductor packaging method according to claim 2, wherein the wafer stacking operation further comprises:
planarizing the first dielectric layer at a top of the protrusion after the second trimming and before the second dielectric layer is formed, wherein
in the step of forming the second dielectric layer, the second dielectric layer is formed on the top and the side wall of the protrusion and on a top of the second to-be-bonded wafer.

4. The semiconductor packaging method according to claim 1, wherein a process of forming the first dielectric layer comprises an atomic layer deposition process or a chemical vapor deposition process.

5. The semiconductor packaging method according to claim 1, wherein a process of forming the second dielectric layer comprises an atomic layer deposition process or a chemical vapor deposition process.

6. The semiconductor packaging method according to claim 1, wherein in the step of forming the first dielectric layer, a material of the first dielectric layer comprises at least one of silicon oxide, silicon nitride, silicon oxynitride, or silicon carbonitride.

7. The semiconductor packaging method according to claim 1, wherein in the step of forming the second dielectric layer, a material of the second dielectric layer comprises at least one of silicon oxide, silicon nitride, silicon oxynitride, or silicon carbonitride.

8. The semiconductor packaging method according to claim 1, wherein in the step of forming the first dielectric layer, a thickness of the first dielectric layer ranges from 500 nanometers to 2900 nanometers.

9. The semiconductor packaging method according to claim 1, wherein in the step of forming the second dielectric layer, a thickness of the second dielectric layer ranges from 50 nanometers to 100 nanometers.

10. The semiconductor packaging method according to claim 1, wherein the first trimming and the second trimming are performed using a blade.

11. The semiconductor packaging method according to claim 1, wherein parameters for the second trimming comprise a trimming depth ranging from 20 microns to 200 microns and a trimming width ranging from 0.5 microns to 5 microns.
